(19) United States
(12) Patent Application Publication
(10) Pub. No.: US 2007/0030649 A1
(43) Pub. Date: Feb. 8, 2007

(54) Electronic device

(75) Inventors: Hsiang-Yi Tsai, Taipei City (TW); Hsiang-Chao Liu, Tao Yuan Shien (TW); Tai-Hung Lin, Tao Yuan Shien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Computer Inc.

(21) Appl. No.: 11/391,950

(22) Filed: Mar. 29, 2006

(30) Foreign Application Priority Data
Aug. 2, 2005 (TW) 94126277

(51) Int. Cl. H05K 7/20; G06F 1/20

(52) U.S. Cl. 361/689; 361/687

(57) ABSTRACT

An electronic device is provided. The electronic device includes a housing and a thermal module. The housing includes an upper shell and a bottom shell. The thermal module is disposed inside the housing. The thermal module includes a first casing and a first block component. The first casing has a first wind opening. The first block component is disposed between the first casing and one of the upper shell or the bottom shell, and is disposed close to the first wind opening for preventing particles from entering the electronic device through the interval between the first casing and the housing.

This application claims the benefit of Taiwan application Serial No. 94126277, filed Aug. 2, 2005, the subject matter of which is incorporated herein by reference.

### BACKGROUND OF THE INVENTION

1. Field of the Invention

The invention relates in general to an electronic device, and more particularly to an electronic device having a block component disposed on the thermal module to comply with the safety standard.

2. Description of the Related Art

Living in today's society where science and technology advance rapidly, various electronic products such as portable computer, desk-top computer, server and power supplier, which bring about convenience, have been widely used in people's everyday life. During the operation of the electronic products, the portable computer in particularity normally generates too much heat, hence affecting the efficiency of the operation. The heat is normally generated from the components such as central processing unit (CPU), hard disc, chip set and so on. Since the design of the product is directed towards slimness, lightweight, and compactness, the generated heat can not be effectively dissipated within a limited space without using a thermal module. The cold air is sucked into the electronic device by the thermal module to dissipate the extra heat generated. However, there are many particles in the air. If a part of metallic particles with larger particle sizes enter the electronic device with the airflow, electric short-circuit may occur to the internal components of the electronic device. Therefore, the electronic device would normally adopt a design in the proximity of the thermal module to comply with safety standard.

Referring to FIG. 1, a diagram of a conventional electronic device equipped with a thermal module is shown. The electronic device 100 includes a housing 20, a thermal module 30 and a plurality of radiating fins 50. The housing 20 comprises a wind opening 21 and a blocking mesh 22. The blocking mesh 22 covers up the wind opening 21 and is disposed on the housing 20. The thermal module 30 is corresponding to the wind opening 21 and fixed inside the housing 20. A plurality of radiating fins 50 are disposed around the thermal module 30.

By means of the operation of the thermal module 30, after the cold air outside the housing 20 is sucked into the thermal module 30 through the wind opening 21, the heat is dissipated through the radiating fin 50. The mesh gap at the blocking mesh 22 disposed at the wind opening 21 must be smaller than an interval complying with the safety standard, so that the safety standard of the electronic device 100 can be met, and that the particles larger than the interval according to the safety standard would not enter the electronic device 100 and cause short-circuit.

With the blocking mesh 22 being disposed at the wind opening 21, the particles larger than the interval according to the safety standard are prevented from entering the electronic device 100. However, the blocking mesh 22 is itself a resistance to the airflow of the cold air, largely affecting the efficiency of the thermal module 30.

### SUMMARY OF THE INVENTION

It is therefore an object of the invention to provide an electronic device. With the design of having the block component disposed on the thermal module, the particles larger than safety standard would be effectively prevented from entering the electronic device through the interval between the thermal module and the housing. Moreover, the dissipating airflow enters the electronic device more smoothly, largely enhancing the efficiency of the thermal module.

The invention achieves the above-identified object by providing an electronic device including a housing and a thermal module. The housing has an upper shell and a lower shell. The thermal module is disposed inside the housing. The thermal module includes a first casing and a first block component. The first casing has a first wind opening. The first block component is disposed between the first casing and one of the upper shell or the lower shell, and is disposed around the first wind opening for preventing particles from entering the electronic device through the interval between the first casing and the housing.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a diagram of a conventional electronic device equipped with a thermal module;

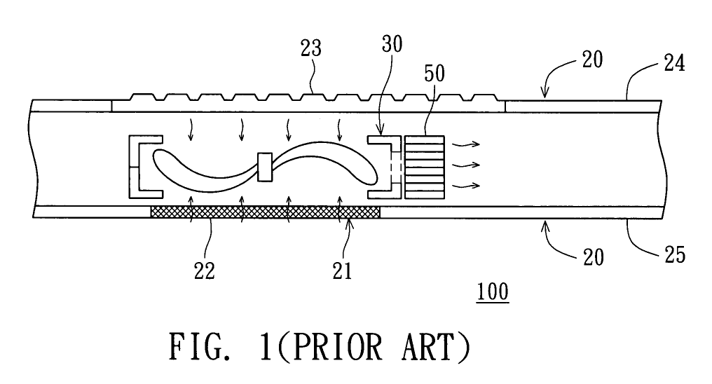

FIG. 2 is a diagram of an electronic device according to a first embodiment of the invention;

FIG. 3 is a top view of the electronic device in FIG. 2; and

FIG. 4 is a diagram of an electronic device according to a second embodiment of the invention.

### DETAILED DESCRIPTION OF THE INVENTION

### First Embodiment

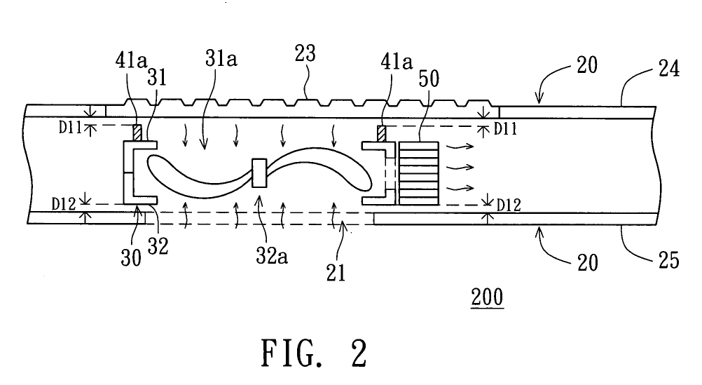

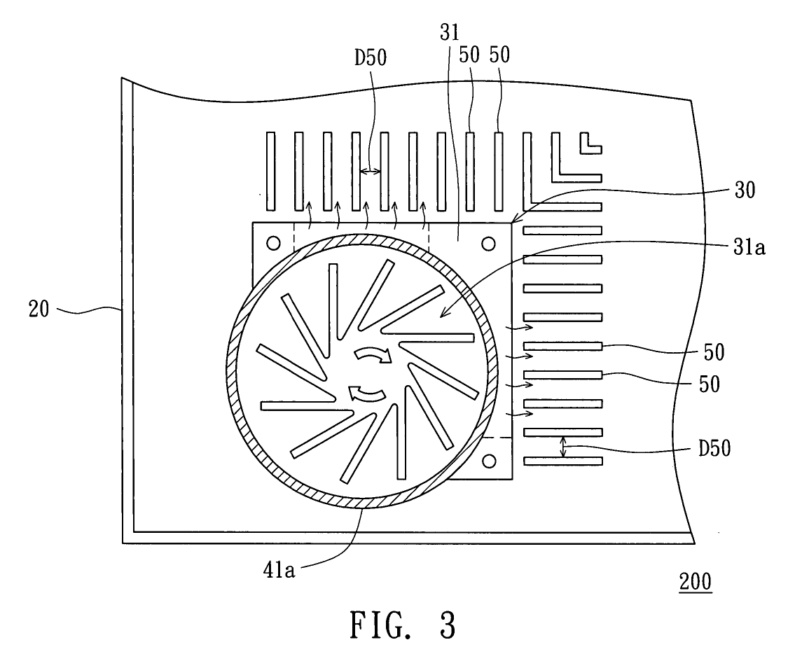

Referring to both FIG. 2 and FIG. 3, FIG. 2 is a diagram of an electronic device according to a first embodiment of the invention, and FIG. 3 is a top view of the electronic device in FIG. 2. The electronic device 200 can be a portable computer, a desk-top computer, a power supplier or a flat display. In the present embodiment, the electronic device 200 is exemplified by a portable computer. The electronic device 200 includes a housing 20 and a thermal module 30. The housing 20 includes an upper shell 24 and a lower shell 25. The upper shell of the housing 20 has a keyboard 23. A wind opening 21 is disposed on the bottom of the housing 20. The internal components of the thermal module 30 comply with a safety standard which is different from the safety standard applicable to the proximity of the thermal module. The thermal module 30 is disposed between the wind opening 21 and the keyboard 23. The thermal module 30 includes a first casing 31, a second casing 32 and a first block component 41a. The first casing 31 and the second casing 32 respectively have a first wind opening 31a and a second wind opening 32a. The first wind opening 31a is close to the keyboard 23 but is facing against the wind opening 21, and the second wind opening 32a is facing towards the wind opening 21. The first block component 41a can be disposed between the first casing 31 and the upper shell 24, close to the first wind opening 31a. Also the first block component 41a can be disposed between the second casing 32 and the upper shell 25, and close to the second wind opening 32a. In the present embodiment, the first block component 41a is disposed between the first casing 31 and the upper shell 24, and close to the first wind opening 31a.

As shown in FIG. 3, in the present embodiment, the first block component 41a is a block ring surrounding the first wind opening 31a. As shown in FIG. 2, the height of the first block component 41a enables the first interval D11 from the upper edge of the first block component 41a to the keyboard 23 to be smaller than the interval according to a safety standard, such as 1 mm for instance. The design of the first block component 41a enlarges the thickness of the thermal module 30, so that the thermal module 30 can be disposed at a lower position, enabling the second interval D12 between the second casing 32 to the housing 20 to comply with the safety standard as well.

After particles enter the thermal module 30 through the wind opening 21 with the airflow, the particles flow inside the thermal module 30. Since the internal components of the thermal module 30 comply with a safety standard, the particles larger than the safety standard would not cause short-circuiting when flowing inside the thermal module 30. Besides, after the particles pass through the wind opening 21 with the airflow, it is possible that the particles might flow to the first interval D11 or the second interval D12 outside the thermal module 30. Since both the first interval D11 and the second interval D12 comply with a safety standard, the particles larger than the safety standard can not enter into the electronic device 200 through the first interval D11 between the thermal module 30 and the keyboard 23 or through the second interval D12 between the thermal module 30 and the housing 20. Consequently, the metallic particles outside the electronic device 200 are prevented from causing short-circuiting to the internal components of the electronic device 200.

The electronic device 200 further includes a plurality of radiating fins 50 disposed around the thermal module 30. As shown in FIG. 3, there is a fin interval D50 between every two of the radiating fins 50. Given that the thermal module 30 complies with the safety standard, and that the intervals D11 and D12 between the thermal module 30 and the housing 20 also comply with the safety standard, the size of the fin interval D50 has a larger flexibility. The fin interval D50 can be larger than a safety interval according to the safety standard such as 1 mm for instance, so that the dissipation efficiency of the radiating fin 50 is enhanced.

As shown in FIG. 3, the first block component 41a of the electronic device 200 of the invention is a mesh and can be made of PC (FR-700) for instance. Despite the first block component 41a is exemplified by a circular block ring, however, anyone who is skilled in the technology of the present embodiment will understand that the technology of the present embodiment is not limited thereto. For example, the first block component 41a can also be a rectangular, or a polygonal block ring. The first block component 41a can also be a non-circular block component 41a disposed between the thermal module 30 and the housing 20 where the interval is larger than the safety interval. The first block component 41a and the first casing 31 can be integrally formed in one piece or coupled together. Any design enabling the first block component 41a to incorporate with the first casing 31 of the thermal module 30 and the housing 20 so that the interval between the top edge of the first block component 41a or the first casing 31 and the housing 20 complies with the safety standard is within the scope of protection of the invention.

Despite the electronic device 200 of the invention is exemplified by the thermal module 30 having the first block component 41a, however, anyone who is skilled in the technology of the present embodiment will understand that the technology of the present embodiment is not limited thereto. For example the thermal module 30 of the electronic device 200 according to the invention can further include a second block component disposed at the second wind opening 32a of the second casing 32. Any design enabling the second block component to incorporate with the second casing 32 of the thermal module 30 and the housing 20 so that the interval between the second casing 32 or the top edge of the second block component and the housing 20 complies with the safety standard is within the scope of protection of the invention.

### Second Embodiment

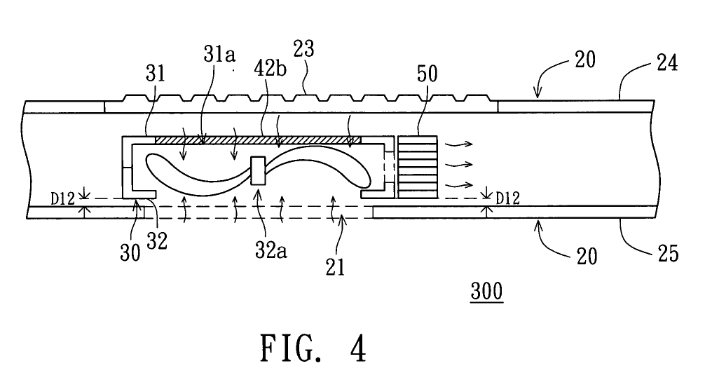

Referring to FIG. 4, a diagram of an electronic device according to a second embodiment of the invention is shown. The electronic device 300 of the present embodiment differs with the electronic device 200 of the first embodiment in the structure of the first block component. As for the same components, the same labels are used and are not repeated here. In the present embodiment, the first block component 42b is a blocking mesh which can be made of PC (FR-700) for instance. The first block component 42b covers up the first wind opening 31a and is disposed on the first casing 31. The mesh gap of the first block component 42b is smaller than the interval according to the safety standard. The interval according to the safety standard can be less than 1 mm for instance.

There is a second interval D22 between the second casing 32 and the housing 20 disposed below. The second interval D22 complies with a safety standard. After particles enter the thermal module 30 through the wind opening 21 with the airflow, the particles flow inside the thermal module 30. Since the internal components of the thermal module 30 comply with a safety standard, the particles larger than the safety standard would not cause short-circuiting when flowing inside the thermal module 30. Besides, after the particles pass through the wind opening 21 with the airflow, it is possible that the particles might flow to the first wind opening 31a of the thermal module 30 or the second interval D22. Since the mesh interval of the first block component 41b is smaller than the interval according to the safety standard, the particles larger than the safety standard can not enter the first interval D21 between the thermal module 30 and the keyboard 23 through the first wind opening 31a, short-circuiting will not occur to the internal components of the electronic device 300. Such that the first interval D21 can be an interval larger than the interval according to the safety standard such as 1 mm for instance. The thermal module 30 can be disposed even lower, enabling the second interval D22 to be smaller than the interval according to the safety standard, so that the particles larger than the safety standard can not enter the electronic device 300 through the second interval D22. Consequently, the metallic particles outside the electronic device 300 are prevented from causing short-circuiting to the internal components of the electronic device 300

The electronic device disclosed in above embodiment of the invention has the design of having the block component disposed on the thermal module, so that the particles larger than safety standard would be effectively prevented from entering the electronic device, lest the metallic particles outside the electronic device might cause short-circuit to internal components of the electronic device. Moreover, the dissipating airflow enters the electronic device more smoothly, largely enhancing the efficiency of the thermal module.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device, comprising:
a housing having an upper shell and a lower shell; and
a thermal module disposed inside the housing, comprising:
a first casing having a first wind opening; and
a first block component disposed between the first casing and one of the upper shell or the lower shell, and is disposed close to the first wind opening for preventing particles from entering the electronic device through the interval between the first casing and the housing.

2. The electronic device according to claim 1, wherein the thermal module further comprising a second casing having a second wind opening, and the interval between the second casing and the housing complies with a safety standard.

3. The electronic device according to claim 2, further comprising a plurality of radiating fins disposed around the thermal module, and the fin interval of the radiating fins is larger than a safety interval according to the safety standard.

4. The electronic device according to claim 1, wherein the thermal module further comprising a second casing having a second wind opening, the thermal module has a second block component disposed at the second wind opening for preventing particles from entering the electronic device through the interval between the second casing and the housing.

5. The electronic device according to claim 4, further comprising a plurality of radiating fins disposed around the thermal module, and the fin interval of the radiating fins larger than a safety interval according to the safety standard.

6. The electronic device according to claim 1, wherein the first block component is a block ring disposed surrounding the first wind opening, and the interval between the upper edge of the block ring and the housing complies with a safety standard.

7. The electronic device according to claim 6, wherein the block ring and the first casing are integrally formed in one piece.

8. The electronic device according to claim 1, wherein the first block component is a blocking mesh for covering up the first wind opening, and the mesh gap of the blocking mesh complies with a safety standard.

9. The electronic device according to claim 8, wherein the bottom of the housing has a wind opening, the thermal module is disposed at the wind opening, and the first wind opening is positioned facing against the wind opening.

10. The electronic device according to claim 1, wherein the electronic device is a portable computer.
